(19) United States
(12) Patent Application Publication
(10) Pub. No.: US 2012/0139600 A1
(43) Pub. Date: Jun. 7, 2012

(54) LOW POWER LATCH USING MULTI-THRESHOLD VOLTAGE OR STACK-STRUCTURED TRANSISTOR

(75) Inventor: Myeong-Eun Hwang, Seongnam-si (KR)

(73) Assignee: SAMSUNG ELECTRONICS CO., LTD., SUWON-SI (KR)

(21) Appl. No.: 13/313,807

(22) Filed: Dec. 7, 2011

(30) Foreign Application Priority Data
Dec. 7, 2010 (KR) 10-2010-0124247

(51) Int. Cl. H03K 3/3562; H03K 3/356

(52) U.S. Cl. 327/203; 327/210

(57) ABSTRACT

Disclosed is a low power latch that includes a low threshold voltage (LThV) inverter inverting an input data value to provide an output data value and including a LThV pull-up transistor and LThV pull-down transistor that operate at a threshold voltage less than a reference threshold voltage. The low power latch also includes a high threshold voltage (HThV) transistor isolating unit configured to isolate a power supply voltage provided to the LThV inverter during a sleep mode indicated by a sleep mode signal, and including a first HThV transistor and a second HThV transistor that operate at a threshold voltage less than the reference threshold voltage.

### CROSS-REFERENCE TO RELATED APPLICATIONS

This application claims the benefits, under 35 U.S.C §119, of Korean Patent Application No. 10-2010-0124247 filed Dec. 7, 2010, the subject matter of which is hereby incorporated by reference.

### BACKGROUND OF THE INVENTION

Exemplary embodiments relate to a low power latch, and more particularly, to a low power latch using threshold voltage scaling (or multi-threshold voltage) or stack-structured transistor

Increase in the integration density of logic circuits, such as microprocessors, microcontroller units (MCUs), digital signal processors (DSPs), etc., necessitates the use of embedded flip-flops in large number. The flip-flop in its many different implementations is a simple circuit capable of storing (or latching) digital data. Flip-flops are basic elements routinely used in the implementation of many different circuits including logic circuits. A flip-flop device generally includes more than one flip-flop and may be implemented from a connected plurality of latches.

Since a substantial number of flip-flop devices may be included within a logic circuit, power consumption becomes an important design consideration. For example, about 40% of the power consumed by some contemporary, high-performance microprocessors is used to drive flip-flop devices within the microprocessors.

Development trends for many logic circuits, including cutting edge microprocessors, concurrently focus on performance improvements and reductions in power consumptions. Increasing integration density and corresponding concerns about thermal loading further emphasize developments trends that seek to reduce power consumption while providing high performance.

In general, a trade-off exists between power consumption and performance in the design and operation of logic circuits and memory devices. For example, problems may arise when a power supply voltage VDD is decreased to reduce overall power consumption. That is, when power consumption is decreased, the performance (e.g., the speed of operation) of the constituent logic circuit also decreases. Alternatively, when the power supply voltage VDD is increased, performance will increase, but power consumption also increases. Thus, it is difficult to unconditionally decrease the power supply voltage VDD in an attempt to decrease power consumption.

One example of a conventional latch and flip-flop device including the conventional latch will now be described with reference to FIG. 1, inclusive of FIGS. 1A, 1B and 1C. FIG. 1A is a circuit diagram illustrating the conventional flip-flop device. FIG. 1B is a circuit diagram illustrating the conventional inverter I1 shown in FIG. 1A. FIG. 1C is a timing diagram illustrating a power leakage interval within the operation of the conventional flip-flop device.

The flip-flop device of FIG. 1A may be used, for example, in a PowerPC (Performance Optimization With Enhanced RISC-Performance Computing) microprocessor. Referring to FIGS. 1A and 1B, the conventional flip-flop device is formed by two latches configured in a master-slave relationship. Like many flip-flop devices, the conventional flip-flop device of FIG. 1A includes inverters I1 and I2. The other elements (e.g., transistors M1-M8) of the flip-flop device shown in FIG. 1A will be readily understood by those skilled in the art. Further, the use of P-type transistor P_{R} and N-type transistor N_{R} to implement the inverter of FIG. 1B will be readily understood by those skilled in the art.

The flip-flop device illustrated in FIG. 1A is known to maintain a relatively reliable operation structure, yet it also presents distinct challenges to efforts intended to decrease overall power consumption. Consider, for example, the power consumption interval of FIG. 1C that is generated when the flip-flop device performs an edge-sensitive operation in response to an applied clock signal (CLK).

It will be appreciated that power may be unnecessarily consumed by inverters I1 and I2 of FIG. 1. That is, as may be understood from FIG. 1C, although the input data signal D goes logically “low” (i.e., a data value of 0), the output data signal Q remains logically “high” (i.e., a data value of 1) while the clock signal is high for a short period of time (i.e., a power leakage period). During this period, power may be unnecessarily consumed even during what should be period of standby operation for the logic device.

### SUMMARY OF THE INVENTION

In one embodiments of the inventive concept provides a low power latch that receives an input data value and provides an output data value, the low power latch comprising; a low threshold voltage (LThV) inverter configured to invert the input data value to provide the output data value, and including a LThV pull-up transistor and LThV pull-down transistor that operate at a threshold voltage less than a reference threshold voltage, and a high threshold voltage (HThV) transistor isolating unit configured to isolate a power supply voltage provided to the LThV inverter during a sleep mode indicated by a sleep mode signal, and including a first HThV transistor and a second HThV transistor that operate at a threshold voltage less than the reference threshold voltage.

In another embodiment, the inventive concept provides a low power flip-flop device that receives an input data value and provides a corresponding output data value. The low power flip-flop comprises a master latch including a first low threshold voltage (LThV) inverter configured to receive and invert the input data value to generate an inverted output data value, and including a first LThV pull-up transistor and a first LThV pull-down transistor operating at a threshold voltage less than a reference threshold voltage, and a first high threshold voltage (HThV) transistor isolating unit configured to isolate a power supply voltage provided to the first LThV inverter during a sleep mode indicated by a sleep mode signal, and including a first transistor and a second transistor that operate at a threshold voltage less than the reference threshold voltage, as well as a slave latch including a second LThV inverter configured to receive and invert the inverted output data value to generate the corresponding output data value, and including a second LThV pull-up transistor and a second LThV pull-down transistor operating at a threshold voltage less than the reference threshold voltage, and a second high threshold voltage (HThV) transistor isolating unit configured to isolate a power supply voltage provided to the second LThV inverter during the sleep mode, and including a third transistor and a fourth transistor that operate at a threshold voltage less than the reference threshold voltage.

In another embodiment, the inventive concept provides a low power latch comprising; an inverter unit configured to invert an input data value and having a pull-up transistor and a pull-down transistor, and a stack-structured transistor isolating unit configured to isolate a power supply voltage provide to the inverter unit during a sleep mode, wherein the stack-structured transistor isolating unit includes at least two pull-up transistors connected in series between the power supply voltage and the pull-up transistor and at least two pull-down transistors connected in series between the pull-down transistor and ground.

### BRIEF DESCRIPTION OF THE FIGURES

The above and other objects and features will become apparent from the following description of embodiments of the inventive concept, as shown in the attached drawings.

FIG. 1A is a circuit diagram illustrating a conventional flip-flop device.

FIG. 1B is a circuit diagram illustrating a conventional inverter within the flip-flop device of FIG. 1B.

FIG. 1C is a timing diagram illustrating a power leakage period for the conventional flip-flop device of FIG. 1A.

FIG. 2A is a circuit diagram illustrating a low power latch using threshold voltage scaling according to an embodiment of the inventive concept.

FIG. 2B is a circuit diagram further illustrating the low threshold voltage inverter unit and a high threshold voltage transistor isolating unit of a low power latch according to an embodiment of the inventive concept.

FIG. 2C is a circuit diagram of a low power latch using threshold voltage scaling according to another embodiment of the inventive concept.

FIG. 2D is a circuit diagram of a low power flip-flop device using threshold voltage scaling according to an embodiment of the inventive concept.

FIG. 2E is a detailed circuit diagram of a first low threshold voltage inverter unit, a first high threshold voltage transistor isolating unit, a second low threshold voltage inverter unit, and a second high threshold voltage transistor isolating unit of a low power flip-flop device according to an embodiment of the inventive concept.

FIG. 2F is a circuit diagram of a low power flip-flop device using threshold voltage scaling according to still another embodiment of the inventive concept.

FIGS. 2G and 2H are circuit diagrams of a low power flip-flop device using threshold voltage scaling, to which a level shifter is added, according to another embodiment of the inventive concept.

FIG. 3 is a graph describing power consumption saving and performance associated with a low power flip-flop device of the inventive concept and a conventional flip-flop device.

FIG. 4A is a circuit diagram of a low power latch using a stack-structured transistor according to another embodiment of the inventive concept.

FIG. 4B is a detailed circuit diagram of an inverter unit and a stack-structured transistor isolating unit of a low power latch according to another embodiment of the inventive concept.

FIG. 4C is a detailed circuit diagram of an inverter unit and a stack-structured transistor isolating unit of a low power latch according to another embodiment of the inventive concept.

### DETAILED DESCRIPTION

Embodiments of the inventive concept will now be described in some additional detail with reference to the accompanying drawings. The inventive concept may, however, be embodied in many different forms and should not be construed as being limited to only the illustrated embodiments. Rather, these embodiments are provided so that this disclosure will be thorough and complete, and will fully convey the scope of the inventive concept to those skilled in the art. Throughout the written description and drawings, like reference numbers and labels are used to denote like or similar elements.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

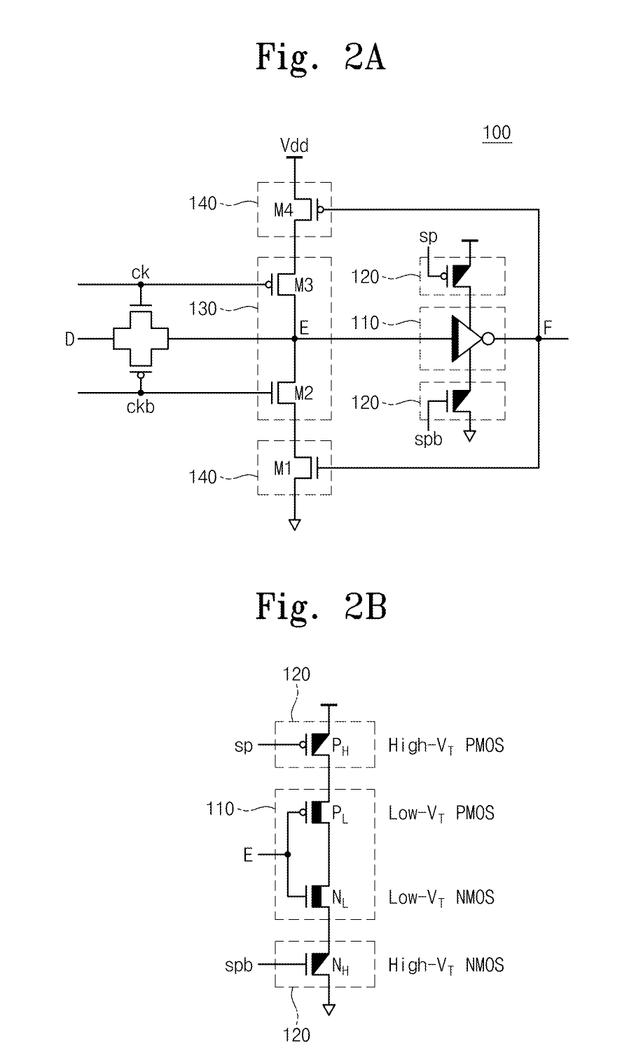

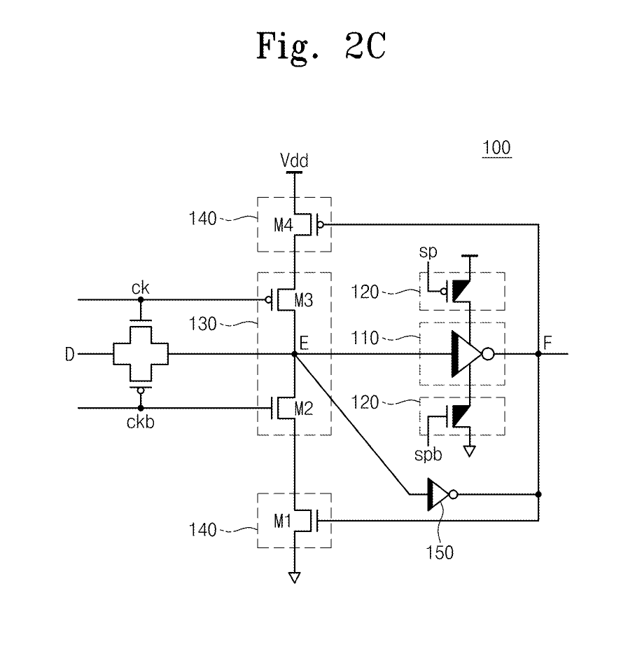

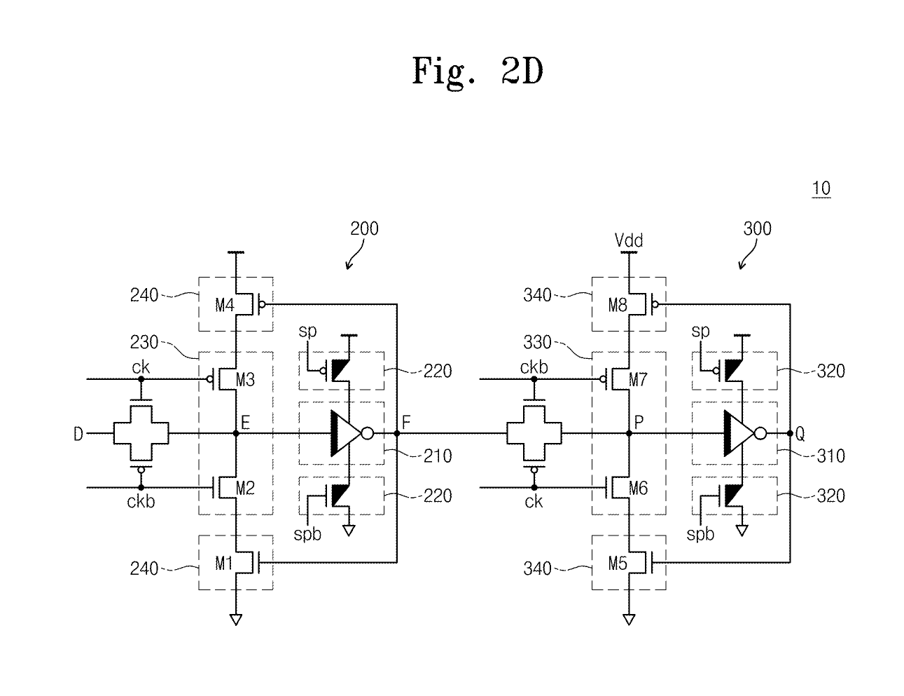

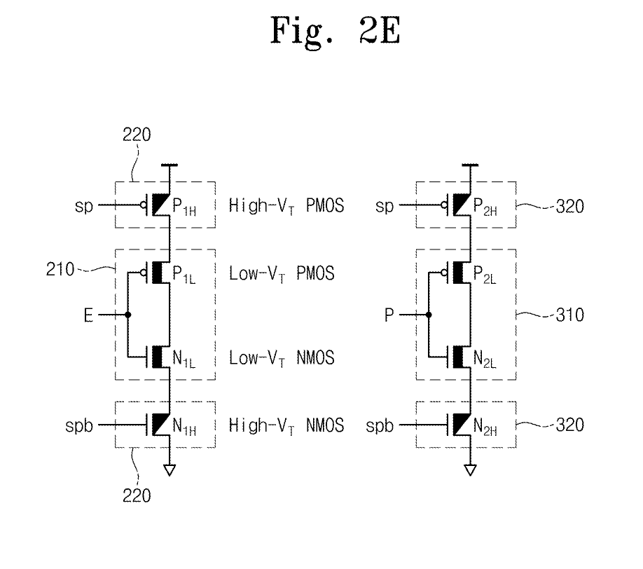

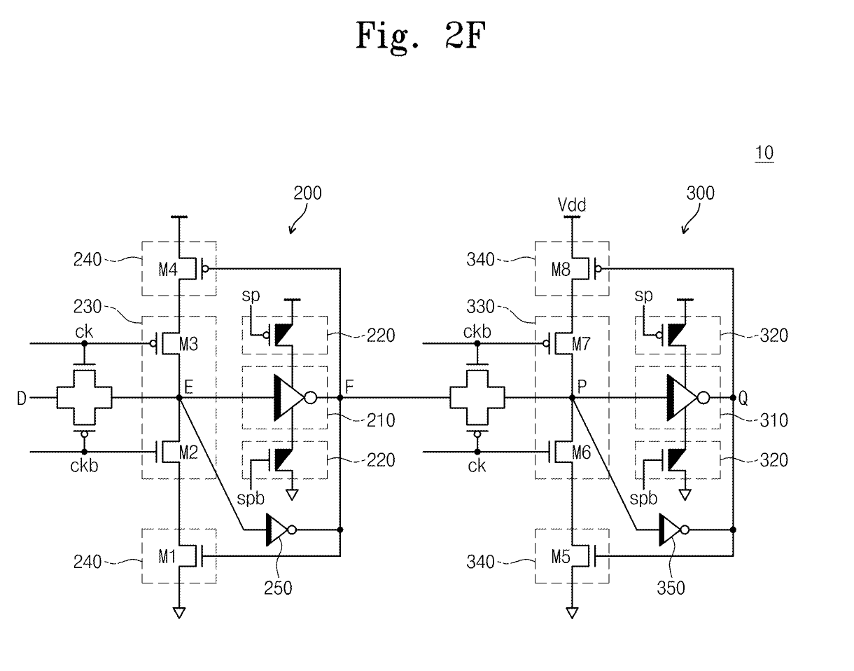

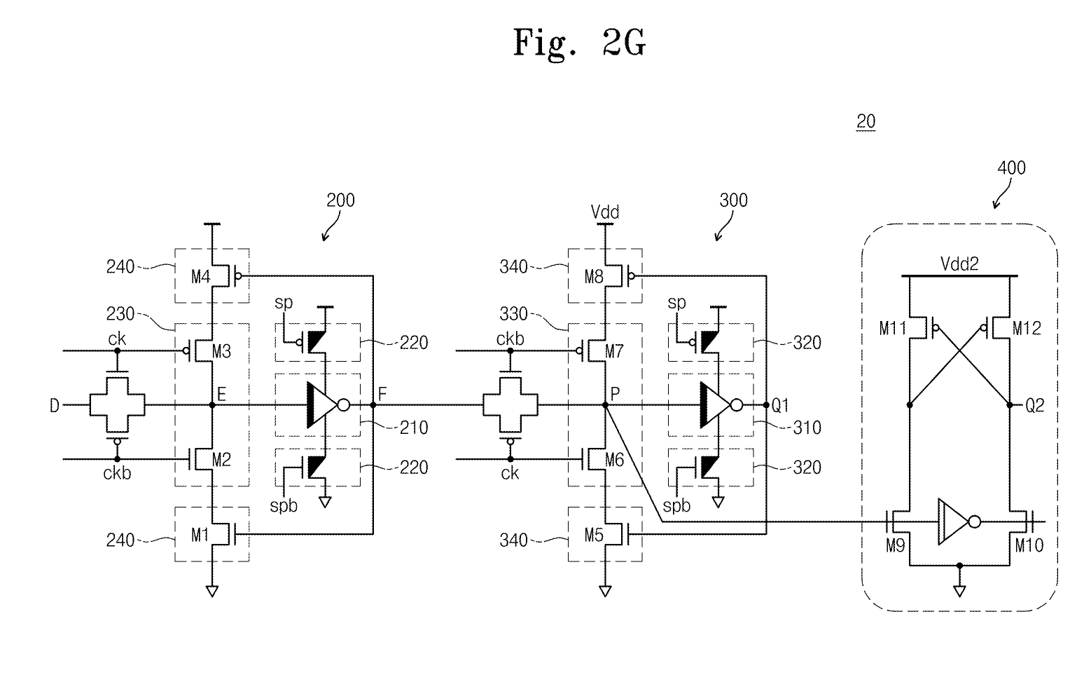

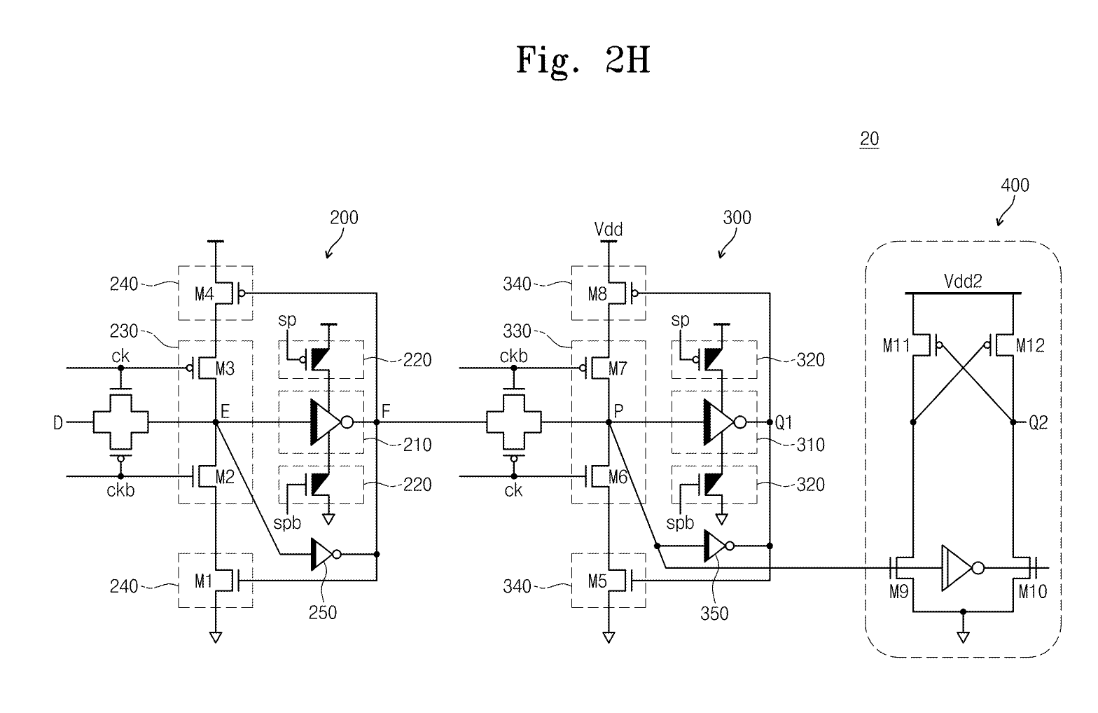

FIG. 2A is a circuit diagram illustrating a low power latch using threshold voltage scaling according to an embodiment of the inventive concept. FIG. 2B is a circuit diagram further illustrating the low threshold voltage (LThV) inverter and a high threshold voltage (HThV) transistor isolating unit of the low power latch of FIG. 2A.

Referring to FIGS. 2A and 2B, a low power latch 100 using threshold voltage scaling (hereinafter, referring to simply as a “low power latch”) comprises a low threshold voltage inverter 110, a high threshold voltage transistor isolating unit 120, a clocked inverter 130, and a feedback inverter 140.

The performance of the low power latch 100 may be improved by implementing the LThV inverter 110 using transistors P_{L} and N_{L} that operate at a threshold voltage less than regular transistor threshold voltages. Yet, some current will leak from the transistors P_{L} and N_{L} even during an off channel state given the relatively low threshold voltages. To prevent this leakage current, the LThV inverter 110 may be controlled so as to be turned ON only during actual operation. This may be accomplished by adding the HThV isolating unit 120 formed of transistors P_{H} and N_{H} each having relatively high threshold voltages. Accordingly, it is possible to prevent power consumption due to unnecessary current leakage using the foregoing arrangement of elements. Those skilled in the art will recognize that the terms “low” threshold voltage and “high” threshold voltage are relative terms, and actual threshold voltage values will vary by design.

The LThV inverter 110 may be used to invert an input data value during a normal mode of operation. In the embodiment of FIG. 2A, the LThV inverter 110 includes a LThV pull-up transistor P_{L} and a LThV pull-down transistor N_{L} that operate at a threshold voltage less than a reference threshold voltage Vt. Since its constituent elements operate at a low threshold voltage as compared with a regular (reference) transistor, the LThV inverter 110 will exhibit relatively higher performance characteristics when operated at a given power supply voltage VDD.

It should be noted at this point that the threshold voltage of a given transistor may be variable according to fabrication process factors, and operating factors like temperature. For example, a given threshold voltage may be decreased or increased by a particular concentration of dopant(s) introduced during a Complementary Metal Oxide Semiconductor (CMOS) process and/or the diameter of a transistor in a case where carbon nanotubes (CNT are used during fabrication).

The HThV transistor isolating unit 120 may be used to isolate the power supply voltage VDD provided to the LThV inverter 110 when the low threshold voltage inverter unit 110 is in a sleep (or standby) mode. The HThV transistor isolating unit 120 of FIGS. 2A and 2B includes a HThV pull-up transistor P_{H} and a HThV pull-down transistor N_{H} that operate at a threshold voltage greater than the reference threshold voltage Vt. The HThV pull-up transistor P_{H} is provided between the power supply voltage VDD and the LThV pull-up transistor P_{L}. The HThV pull-down transistor N_{H} is provided between the LThV pull-down transistor N_{L} and ground. If the HThV transistor isolating unit 120 operates at a relatively high threshold voltage, the current leaked by the LTHV inverter 110 during the sleep mode may be isolated. Thus, power consumption may be reduced.

In the low power latch of FIGS. 2A and 2B, the HThV pull-up transistor P_{H} is connected between the power supply voltage VDD and the source of the LTHV pull-up transistor P_{L}. The HThV pull-up transistor P_{H} is turned ON by an active sleep signal (sp) applied to its gate as an input signal. When turned ON, the HThV pull-up transistor P_{H} supplies the power supply voltage VDD to the LThV inverter 110. The HThV pull-down transistor N_{H} is connected between the LThV pull-down transistor N_{L} and ground. The HThV pull-down transistor N_{H} is turned ON by an active complementary (“bar”) sleep signal (spb) applied to its gate as an input signal. Thus, the “active” state logic levels for the sleep signal (sp) and the complementary sleep signal (spb) are opposite (e.g., high verses low).

The clocked inverter 130 of FIG. 2A includes a pull-up transistor M3 gated by a master clock signal (ck) and a pull-down transistor M2 gated by a slave or complementary clock signal (ckb). Thus, the “active” state logic levels for the slave clock signal (ckb) and master clock signal (ck) are opposite (e.g., high verse low).

The feedback inverter 140 of FIG. 2A includes a P-type pull-up transistor M4 gated by an output data value F and connected between the power supply voltage VDD and the pull-up transistor M3. The feedback inverter 140 of FIG. 2A also includes a N-type pull-down transistor M1 gated by the output data value F and connected between the pull-down transistor M2 and ground. The respective size(s) of the pull-up and pull-down transistors M4 and M1 may be different from the respective size(s) of the pull-up and pull-down transistors M3 and M2 as various designs demand.

Using a low power latch like the one illustrated in FIGS. 2A and 2B consistent with embodiments of the inventive concept, the conventional trade-off between performance and power consumption may be avoided by improving performance using the LThV inverter 110 while reducing power consumption using the HThV transistor isolating unit 120. Those skilled in the art will recognize that embodiments of the inventive concept like the low power latch 100 of FIG. 2A may be used within many different types of flip-flop devices, including a JK flip-flop device, an RS flip-flop device, a D flip-flop device, and the like.

FIG. 2C is a circuit diagram of a low power latch using threshold voltage scaling according to another embodiment of the inventive concept.

Referring to FIG. 2C, the low power latch 100 previously described in relation to FIG. 2A is modified to further include a data retaining inverter 150. In the case of low power latch 100 described in relation to FIG. 2A, the LThV inverter 110 will not retain the output data value F upon switching into the sleep mode. That is, the last output data value F may be lost upon switching to the sleep mode. However, in the low power latch 100 of FIG. 2C, the output data value F may be stably retained upon switching into the sleep mode by the addition of the data retaining inverter 150 connected in parallel with the LThV inverter 110. Thus, the output data value F will not be lost upon switching into the sleep mode. In certain embodiments of the inventive concept, the HThV transistor isolating unit 120 may be configured so that it does not surround the data retaining inverter 150.

The data retaining inverter 150 may be configured to operate at a threshold voltage greater than the reference threshold voltage Vt. It may be desirable for the data retaining inverter 150 to have a relatively small size and/or to operate at a relatively high threshold voltage to reduce overall power consumption taking into account both leakage current and active power current consumption.

Hereafter, various flip-flop devices incorporating the low power latch 100 of FIGS. 2A through 2C will be described with reference to FIGS. 2D through 2G.

FIG. 2D is a circuit diagram of a low power flip-flop device using threshold voltage scaling according to an embodiment of the inventive concept. FIG. 2E is a circuit diagram further illustrating the first LTHV inverter, the first HThV transistor isolating unit, the second LTHV inverter, and the second HThV transistor isolating unit of the low power flip-flop device of FIG. 2D according to an embodiment of the inventive concept.

Referring to FIGS. 2D and 2E, a low power flip-flop device using threshold voltage scaling (hereinafter, referred to simply as a “low power flip-flop device”) 10 comprises a master latch 200 and a slave latch 300. The master latch 200 receive an input data value D and provides an inverted output data value F. The slave latch 300 receives the inverted output data value F from the master latch 200 as an input data value P and ultimately provides an output data value Q. As a result, the low power flip-flop device 10 receives and latches the input data value D to provide a corresponding output data value Q. Because the input data value D is delayed by some delay time while latch-passing through the low power flip-flop device 10, the low power flip-flop device 10 may be used to store (latch) the input data value or merely to delay the data signal by the given delay time.

The master latch 200 of FIG. 2D includes a first LThV inverter 210, a first HThV transistor isolating unit 220, a first clocked inverter 230, and a first feedback inverter 240. The slave latch 300 includes a second LThV inverter 310, a second HThV transistor isolating unit 320, a second clocked inverter 330, and a second feedback inverter 340.

The low power flip-flop device 10 is capable of operating at relatively low power by configuring each of the first and second LThV inverters 210 and 310 corresponding to the shortest direct path between an data value input D and an data value output Q in order to operate at a threshold voltage less than a given reference threshold voltage Vt. As a result, the performance of the low power flip-flop device 10 may be improved. If the threshold voltage of certain transistors is decreased, the amount of current leaked during the off channel state may increase. To prevent this from happening, the first HThV transistor isolating unit 220 and the second HThV transistor isolating unit 320 are provided in the embodiment illustrated in FIG. 2D. Such provision, enables the first and second LThV inverters 210 and 320 to operate only during intended actual operation (e.g., a normal mode). Thus, power consumption may be reduced by avoiding such leakage. Hereafter, possible implementation embodiments for the master and slave latches 200 and 300 of FIG. 2D will be described.

First, one possible example of the master latch 200 will be described.

The first LThV inverter 210 inverts an input data value and may include a LThV pull-up transistor P_{1L} and a LThV pull-down transistor N_{1L} that operate at a threshold voltage less than the reference threshold voltage Vt. If the first LThV inverter 210 is configured to operate at the relatively low threshold voltage, as described above, it is possible to improve performance while not changing a given power supply voltage VDD.

The first HThV transistor isolating unit 220 may be used to isolate the power supply voltage VDD provide to the first LThV inverter 210 when the first LThV inverter 210 is in the sleep mode. The first HThV transistor isolating unit 220 may include a HThV pull-up transistor P_{1H} and a HThV pull-down transistor N_{1H} that operate at a threshold voltage greater than the reference threshold voltage Vt. By having a higher threshold voltage, the first HThV transistor isolating unit 210 may prevent current leakage via the pull-up and pull-down transistors P_{1L} and N_{1L}. Since the threshold voltage is relatively high, channels of the HThV pull-up and pull-down transistors P_{1L} and N_{1L} of the first HThV transistor isolating unit 220 may not be closely formed. Hence, leakage current may all but be eliminated. This means the current flowing to the first LThV inverter 210 from the power supply voltage VDD is isolated. That is, power is not lost my current leakage through the first LThV inverter 210. A more detailed description of this operation follows.

The pull-up transistor P_{1E} may be connected between the power supply voltage VDD and the source of the pull-up transistor P_{1L}. The pull-up transistor P_{1H} is turned ON by an active level of the sleep signal (sp) applied to its gate in order to supply the power supply voltage VDD to the first LThV inverter 210. The pull-down transistor N_{1H} is connected between the source of the pull-down transistor N_{1L} and ground. The pull-down transistor N_{1H} is turned ON by an active level of the complementary sleep signal (spb) applied to its gate as an input signal.

The first clocked inverter 230 includes a pull-up transistor M3 operating in response to the master clock signal (ck) and a pull-down transistor M2 operating in response to a slave clock signal (ckb).

The first feedback inverter 240 includes a pull-up transistor M4 that operates in response to the inverted output data value F and is connected between the power supply voltage VDD and the pull-up transistor M3. The first feedback inverter 240 also includes a pull-down transistor M1 that operates in response to the inverted output value F and is connected between the pull-down transistor M2 and ground.

One possible example of the slave latch 300 will be now described.

The second LThV inverter 310 inverts the inverted output data value F received from the master latch 200 during a normal mode, and includes a pull-up transistor P_{2L} and a pull-down transistor N_{2L} that operate at a low threshold voltage less than the reference threshold voltage Vt. The second LThV inverter 310 may operate in a manner similar to that of the first LThV inverter 210. Hence, this description will be omitted to avoid redundancy.

The second HThV transistor isolating unit 320 may be used to isolate the power supply voltage VDD applied to the second LThV inverter 310 when the second LThV inverter 310 is in the sleep mode. The second HThV transistor isolating unit 320 includes a pull-up transistor P_{2H} and a pull-down transistor N_{2H} that operate at a threshold voltage greater than the reference threshold voltage Vt. The second HThV transistor isolating unit 320 may operate in a manner similar to that of the first HThV transistor isolating unit 220.

The pull-up transistor P_{2H} is connected between the power supply voltage VDD and the source of the pull-up transistor P_{2L}. The pull-up transistor P_{2H} is turned ON in response to the active level of the sleep signal (sp) applied to its gate as an input signal in order to supply the power supply voltage VDD to the second LTHV inverter 310. The pull-down transistor N_{2H} is connected between the source of the pull-down transistor N_{2L} and ground. The pull-down transistor N_{2H} is turned ON in response to an active level of the complementary sleep signal (spb) applied to its gate as an input signal.

The second clocked inverter 330 includes a pull-up transistor M7 that operates in response to the active level of the master clock signal (ck) and a pull-down transistor M6 that operates in response to the slave clock signal (ckb).

The second feedback inverter 340 includes a pull-up transistor M8, that operates in response to the output data value Q and is connected between the power supply voltage VDD and the pull-up transistor M7. The second feedback inverter 340 also includes a pull-down transistor M5 that operates in response to the output data value Q and is connected between the pull-down transistor M6 and ground.

FIG. 2F is a circuit diagram of a low power flip-flop device using threshold voltage scaling according to still another embodiment of the inventive concept.

Referring to FIG. 2F, a low power flip-flop device 10 further comprises a first data retaining inverter 250 and a second data retaining inverter 350 as compared with the low power flip-flop device 10 described in relation to FIG. 2D. In the case of the low power flip-flop device 10 described in relation to FIG. 2D, the first and second LThV inverters 210 and 310 may not respectively retain the inverted output data value F and the output data value Q upon switching into the sleep mode.

However, the low power flip-flop device 10 in FIG. 2F is able to retain data output values F and Q upon entering the sleep mode by connecting the first data retaining inverter 250 in parallel with the first LThV inverter unit 210 and connecting the second data retaining inverter 350 in parallel with the second LThV inverter 310, respectively. With this configuration, output data values will not be lost upon switching into the sleep mode. The first and second HThV transistor isolating units 220 and 320 may be configured not to surround the first and second data retaining inverters 250 and 350, respectively.

Herein, the first and second data retaining inverter units 250 and 350 may be configured to operate at a threshold voltage greater than the reference threshold voltage Vt. The first and second data retaining inverters 250 and 350 may be used to retain data even through the sleep mode. It may be desirable for the first and second data retaining inverters 250 and 350 to have a small size or to operate a relatively high threshold voltage to reduce overall power consumption taking into account leakage current and an active power current consumption.

FIGS. 2G and 2H are circuit diagrams illustrating a low power flip-flop device using threshold voltage scaling including a level shifter according to another embodiment of the inventive concept.

Referring to FIG. 2G, if scaling of the power supply voltage is applied to certain logic circuits, it is useful to use a low power flip-flop device including a level shifter 400. The level shifter 400 is connected to receive as an input data value the input data value P received by the slave latch 300 and shift the level of the input data value signal upward from the power supply voltage Vdd to a boosted power supply voltage Vdd2 greater than the power supply voltage Vdd. Unlike the low power flip-flop device described in FIG. 2G, a low power flip-flop device including a data retaining inverter 350 can be used together with the level shifter 400 as illustrated in FIG. 2H.

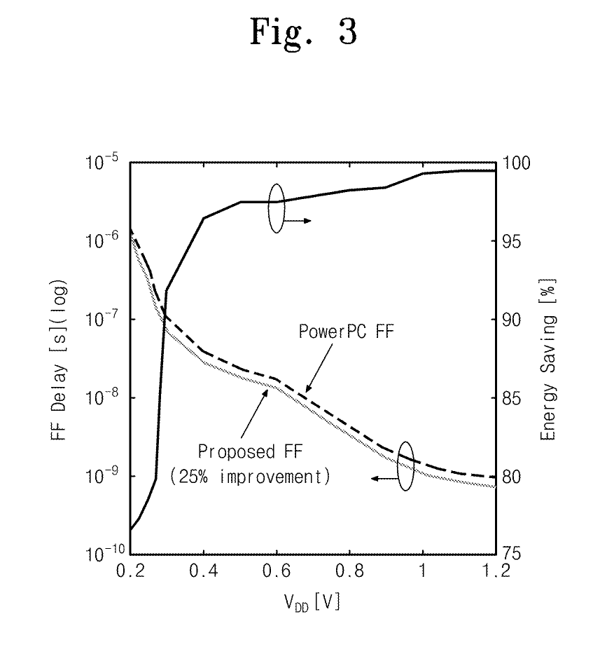

FIG. 3 is a graph describing power consumption savings and performance associated with a low power flip-flop device according to an embodiment of the inventive concept as compared with an analogous conventional flip-flop device.

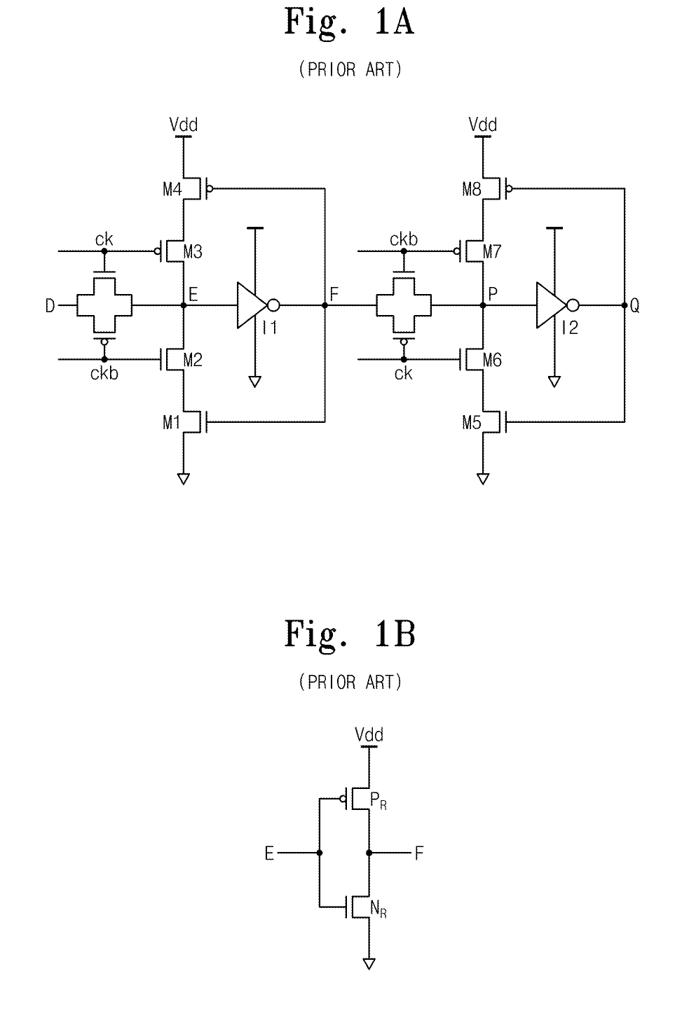

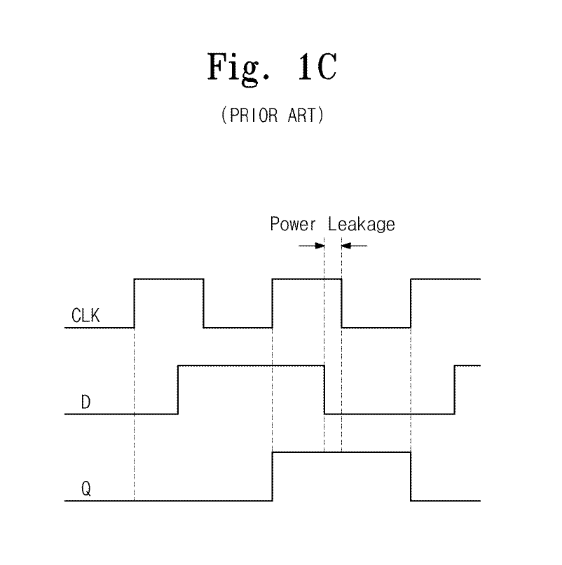

In FIG. 3, a conventional Power flip-flop (FF) device like the one described in relation to FIG. 1C is assumed and compared with an analogous use of a proposed, low power flip-flop (FF) device according to an embodiment of the inventive concept. The conventional flip-flop device and the low power flip-flop device 10 show about the same speed performance in relation to a given range of power supply voltages VDD. Yet, the low power flip-flop device 10 shows dramatically reduced (e.g., about 25%) power consumption across the range of power supply voltages.

Since the conventional flip-flop device is designed without considering of the power saving, it shows the performance close to 0 at a power saving aspect. However, the low power flip-flop device 10 shows the power saving close to 95% between 1V and 1.2V being a power supply voltage VDD which is mainly used. Although postulating a power saving rate of about 50%, power may be saved at an overall rate of about 20% for a logic circuit such as a contemporary microprocessor considering that the power consumed by the flip-flop device is about 40% of the total power consumption.

As a result, the conventional trade-off between performance and power savings may be significantly modified. And remarkable power savings may be had without reducing performance over logic circuits that use conventional flip-flop devices.

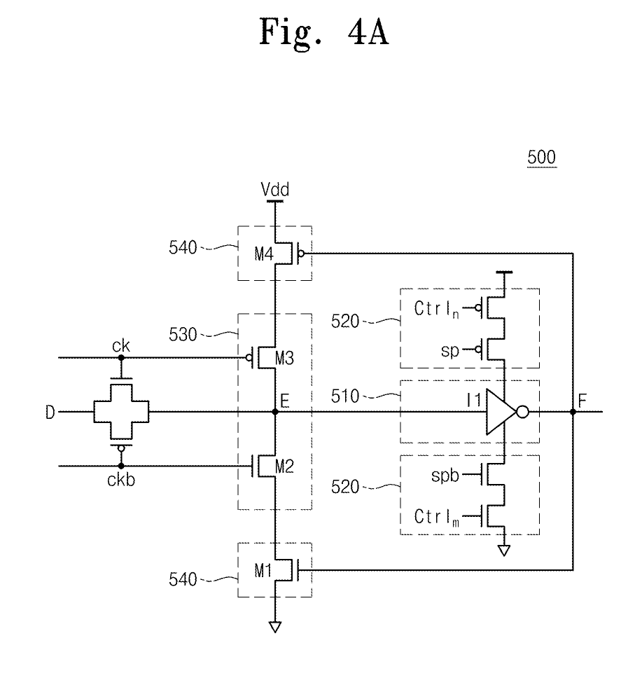

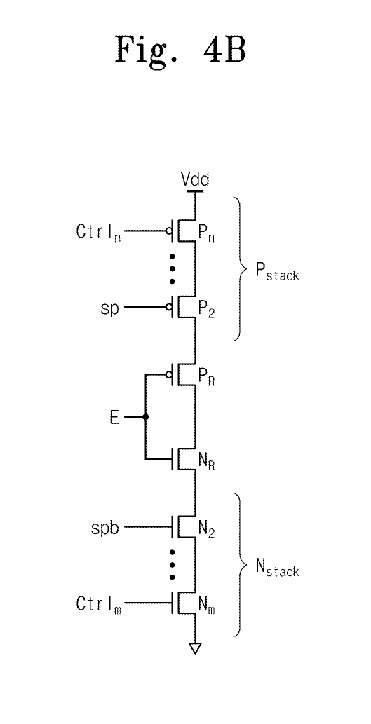

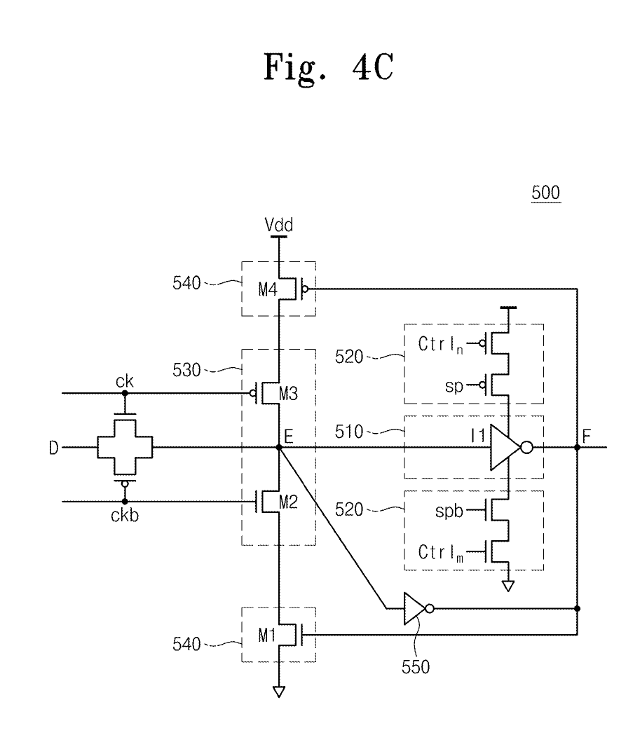

FIG. 4A is a circuit diagram of a low power latch using a stack-structured transistor according to another embodiment of the inventive concept. FIG. 4B is a circuit diagram further illustrating the inverter unit and stack-structured transistor isolating unit of a low power latch of FIG. 4A.

Referring to FIGS. 4A and 4B, a low power latch using a stack-structured transistor (hereinafter, referred to simply as a “low power latch”) 500 comprises an inverter 510 and a stack-structured transistor isolating unit 520.

The low power latch 500 also includes regular transistors that operate at a reference threshold voltage and do not use threshold voltage scaling. The stack-structured transistor isolating unit 520 includes stacked regular transistors, and may be used to isolate the power supply voltage provided to the inverter 510. This may be because a power supply voltage passes through multiple transistors. Below, a more detailed description is provided.

The inverter 510 of FIGS. 4A and 4B include a pull-up transistor P_{R} and a pull-down transistor N_{R} that operate to invert an input data value during a normal mode.

The stack-structured transistor isolating unit 520 may be used to isolate the power supply voltage VDD provided to the inverter 510 when the inverter 510 is in the sleep mode. The stack-structured transistor isolating unit 520 includes a plurality of pull-up transistors P_{stack} in series connected between the power supply voltage VDD and the pull-down transistor P_{R}, and a plurality of pull-down transistors N_{stack} series connected between the pull-down transistor N_{R} and ground. The stack-structured transistor isolating unit 520 may prevent current leakage by blocking current at multiple steps using a plurality of transistors.

The plurality of pull-up transistors P_{stack} is connected between the power supply voltage VDD and the source of the pull-up transistor P_{R}. The plurality of pull-up transistors P_{stack} is turned ON in response to active level(s) of a plurality of control signals (sp) and (ctrln) applied as gate input signals in order to supply the power supply voltage to the inverter 510. The plurality of pull-down transistors N_{stack} is connected between the source of the pull-down transistor N_{R} and ground. The plurality of pull-down transistors N_{stack} is turned ON in response to the active levels of the plurality of complementary control signals (spb) and (ctrlm) applied as gate input signals. Herein, the control signals (sp), (spb), (ctrln), and (ctrlm) are various independent control signals that will be understood by those skilled in the art. For example, the signals (sp) and (spb) may be control signals that switch operation of the inverter 510 in relation to a sleep mode. The signals ctrln and ctrlm may be a control signal for switching the inverter unit 510 into a sleep mode by a timer. The number of control signals is not limited thereto. The number and type of control signals will vary with design demands.

With the above description, it is possible to reduce power consumption using a stack-structured transistor isolating unit 520. The low power latch 500 may be applied to many different types of flip-flop devices, including the JK flip-flop device, RS flip-flop device, D flip-flop device, and the like.

FIG. 4C is a circuit diagram illustrating a modified inverter unit and a stack-structured transistor isolating unit within a low power latch according to another embodiment of the inventive concept.

A low power latch 500 illustrated in FIG. 4C is substantially similar to that of FIG. 4A, except a data retaining inverter 550 is connected in parallel with the inverter 510.

With a low power latch using threshold voltage scaling or stack-structure transistor, overall performance may be improved using a transistor having a relatively low threshold voltage. As a result, current may leak through the transistor channel due to the low threshold voltage. To prevent such current leakage, a transistor having a relative high threshold voltage may be added to the low power latch.

The above-disclosed subject matter is to be considered illustrative, and not restrictive, and the appended claims are intended to cover all such modifications, enhancements, and other embodiments, which fall within the scope of the inventive concept. Thus, to the maximum extent allowed by law, the scope is to be determined by the broadest permissible interpretation of the following claims and their equivalents, and shall not be restricted or limited by the foregoing detailed description.

What is claimed is:

1. A low power latch that receives an input data value and provides an output data value, the low power latch comprising:
a low threshold voltage (LThV) inverter configured to invert the input data value to provide the output data value, and including a LThV pull-up transistor and LThV pull-down transistor that operate at a threshold voltage less than a reference threshold voltage; and
a high threshold voltage (HThV) transistor isolating unit configured to isolate a power supply voltage provided to the LThV inverter during a sleep mode indicated by a sleep mode signal, and including a first HThV transistor and a second HThV transistor that operate at a threshold voltage less than the reference threshold voltage.

2. The low power latch of claim 1, further comprising:
a data retaining inverter connected in parallel with the LThV inverter and configured to retain the output data value when the LThV inverter switches to the sleep mode.

3. The low power latch of claim 2, wherein the first transistor is a HThV pull-up transistor connected between the power supply voltage and the LThV pull-up transistor, and
the second transistor is a HThV pull-down transistor connected between the LThV pull-down transistor and ground.

4. The low power latch of claim 3, wherein the HThV pull-up transistor is turned ON in response to the sleep mode signal to supply the power supply voltage to the LThV pull-up transistor, and
the HThV pull-down transistor is turned ON in response to a complementary version of the sleep mode signal to ground the LThV pull-down transistor.

5. The low power latch of claim 4, wherein the data retaining inverter is has a threshold voltage greater than the reference threshold voltage.

6. The low power latch of claim 2, further comprising:
a clocked inverter including a first pull-up transistor operating in response to a clock signal and a first pull-down transistor operating in response to a complementary version of the clock signal; and
a feedback inverter including a second pull-up transistor connected between the power supply voltage and the first pull-up transistor and a second pull-down transistor connected between the first pull-down transistor and ground, wherein the second pull-up transistor and the second pull-down transistor operate in response to the output data value.

7. The low power latch of claim 6, wherein the first and second pull-up transistors and the first and second pull-down transistors operate at a threshold voltage greater than the reference threshold voltage.

8. A low power flip-flop device that receives an input data value and provides a corresponding output data value, the low power flip-flop comprising:
a master latch comprising;
a first low threshold voltage (LThV) inverter configured to receive and invert the input data value to generate an inverted output data value, and including a first LThV pull-up transistor and a first LThV pull-down transistor operating at a threshold voltage less than a reference threshold voltage, and
a first high threshold voltage (HThV) transistor isolating unit configured to isolate a power supply voltage provided to the first LThV inverter during a sleep mode indicated by a sleep mode signal, and including a first transistor and a second transistor that operate at a threshold voltage less than the reference threshold voltage; and
a slave latch comprising:
a second LThV inverter configured to receive and invert the inverted output data value to generate the corresponding output data value, and including a second LThV pull-up transistor and a second LThV pull-down transistor operating at a threshold voltage less than the reference threshold voltage, and
a second high threshold voltage (HThV) transistor isolating unit configured to isolate a power supply voltage provided to the second LThV inverter during the sleep mode, and including a third transistor and a fourth transistor that operate at a threshold voltage less than the reference threshold voltage.

9. The low power flip-flop device of claim 8, further comprising:
a first data retaining inverter connected in parallel with the first LThV inverter to retain the inverted output data value during the sleep mode; and
a second data retaining inverter connected in parallel with the second LThV inverter to retain the output data value during the sleep mode.

10. The low power flip-flop device of claim 9, wherein the first transistor is a HThV pull-up transistor connected between the power supply voltage and the first LThV pull-up transistor,
the second transistor is a HThV pull-down transistor connected between the first LThV pull-down transistor and ground,
the third transistor is a HThV pull-up transistor connected between the power supply voltage and the second LThV pull-up transistor, and
the fourth transistor is a HThV pull-down transistor connected between the second LThV pull-down transistor and ground.

11. The low power flip-flop of claim 10, wherein the first and third HThV pull-up transistors are respectively turned ON in response to the sleep mode signal to respectively supply the power supply voltage to the LThV pull-up transistors of the first and second LThV inverters, and
the second and fourth HThV pull-down transistors are respectively turned ON in response to a complementary version of the sleep mode signal to respectively ground the LThV pull-down transistors of the first and second inverters.

12. The low power flip-flop of claim 11, wherein each one of the first and second data retaining inverters has a threshold voltage greater than the reference threshold voltage.

13. The low power flip-flop of claim 9, wherein the master latch further comprises:
a first clocked inverter (FCI) including a FCI pull-up transistor operating in response to a clock signal and a FCI pull-down transistor operating in response to a complementary version of the clock signal; and
a first feedback inverter (FFI) including a FFI pull-up transistor connected between the power supply voltage and the FCI pull-up transistor and a FFI pull-down transistor connected between the FCI pull-down transistor and ground, wherein the FFI pull-up transistor and the FFI pull-down transistor operate in response to the inverted output data value; and
the slave latch further comprises:
a second clocked inverter (SCI) including a SCI pull-up transistor operating in response to the clock signal and SCI pull-down transistor operating in response to the complementary version of the clock signal; and
a second feedback inverter (SFI) including a SFI pull-up transistor connected between the power supply voltage and the SCI pull-up transistor and a SFI pull-down transistor connected between the SFI pull-down transistor and ground, wherein the SFI pull-up transistor and the SFI pull-down transistor operate in response to the output data value.

14. The low power flip-flop of claim 13, wherein the FCI, FFI, SCI, and SFI pull-up transistors and the FCI, FFI, SCI and SFI pull-down transistors operate at a threshold voltage greater than the reference threshold voltage.

15. The low power flip-flop device of claim 8, further comprising:
a level shifter that receives the inverted output data value provided to the master latch and shifts the inverted output data value from a power supply voltage level to a boosted power supply voltage level greater than the power supply voltage level.

16. The low power flip-flop device of claim 9, further comprising:
a level shifter that receives the inverted output data value provided by the master latch and shifts the inverted output data value from a power supply voltage level to a boosted power supply voltage level greater than the power supply voltage level.

17. A low power latch comprising:
an inverter unit configured to invert an input data value and having a pull-up transistor and a pull-down transistor; and
a stack-structured transistor isolating unit configured to isolate a power supply voltage provide to the inverter unit during a sleep mode,
wherein the stack-structured transistor isolating unit includes at least two pull-up transistors connected in series between the power supply voltage and the pull-up transistor and at least two pull-down transistors connected in series between the pull-down transistor and ground.

18. The low power latch of claim 17, wherein the at least two pull-up transistors are configured to supply the power supply voltage to the inverter unit in response to a sleep mode signal indicating the sleep mode and a control signal, and the at least two pull-down transistors are turned ON in response to complementary versions of the sleep mode signal and the control signal.

19. The low power latch of claim 18, wherein the pull-up and pull-down transistors, the at least two pull-up transistors, and the at least two pull-down transistors operate at a regular threshold voltage.

20. The low power latch of claim 19, further comprising:
a data retaining inverter connected in parallel with the inverter unit and configured to retain the output data value when the inverter unit switches to the sleep mode.
